(19) United States
(12) Patent Application Publication
(10) Pub. No.: US 2003/0030504 A1
(43) Pub. Date: Feb. 13, 2003

(54) Tunable impedance matching circuit for RF power amplifier

(75) Inventors: Nagaraj Dixit, Gilbert, AZ (US); Prasanth Perugupall, Tempe, AZ (US); Larry Leighton, Scottsdale, AZ (US)

Correspondence Address: LYON & LYON LLP, 633 WEST FIFTH STREET, SUITE 4700, LOS ANGELES, CA, 90071, US

(73) Assignee: Telefonaktiebolaget LM Ericsson

(21) Appl. No.: 09/927,298

(22) Filed: Aug. 10, 2001

(51) Int. Cl. H03H 11/28

(52) U.S. Cl. 333/32; 330/305

(57) ABSTRACT

A tunable impedance matching circuit is provided for tuning an active device, such as, e.g., a field effect transistor, in a RF power amplifier circuit. The matching circuit includes an adjustable length transmission line for electrically coupling a RF signal between an active device and its source and a load. The transmission line, which has a length approximately equal to a quarter of a wavelength of the fundamental frequency of a RF signal being amplified, is adjusted to achieve selected performance characteristic(s) of the amplifier, such as, e.g., input return loss.

### BACKGROUND OF THE INVENTION

The invention relates generally to radio frequency (RF) power amplifiers and, more particularly, to tunable impedance matching circuits for RF power amplifier circuits.

The use of RF power transistor devices as signal amplifiers in wireless communication applications is well known. With the considerable recent growth in the demand for wireless services, such as personal communication services, the operating frequency of wireless networks has increased dramatically and is now well into the gigahertz frequencies. Radio frequency (RF) power transistors are commonly used in amplification stages for radio base station amplifiers. Such transistors are also widely used in other RF-related applications, such as cellular telephones, paging systems, navigation systems, television, avionics, and military applications.

Production of RF power transistor amplifiers on a large-volume basis is traditionally a problem, because of variables that the individual elements possess. In particular, the transistor devices have natural variances in input capacitance, gain and phase shift. Thus, in commercial implementations, significant time and effort is needed to first characterize a particular transistor device over the range of expected operating frequencies and voltages, and then attempt to build many devices using like materials, which deliver similar desired performance. However, due to the variations in transistors' and various other elements over identical operating frequencies and voltages, the ability to successfully tune transistor devices is limited.

Consistent performance of high frequency RF power transistors is, thus, problematic due to their intrinsic variations. These variances must be compensated for in the amplification circuits to achieve reliable and consistent performance. For example, DC biasing and temperature compensation circuits are traditionally employed in the circuits to compensate for inherent differences between individual power transistor devices and for changes in temperature during operation.

Further, RF power amplifiers must be tuned for optimal performance. Presently, RF power amplifiers are assembled by first placing the circuit's components on a substrate (e.g., a PC board) and securing the RF power transistors in place. The amplifier is then manually or automatically tuned, either of which requires complicated test equipment. Existing manual tuning methods involve adjusting variable capacitors, which are included in the circuits solely for tuning. The capacitors are relatively expensive; thus, their elimination would significantly reduce the cost of a RF power amplifier. Further, the amount of adjustment needed is not easily determined, and the methods used are iterative and sometimes intuitive; thus, the process can be time consuming. Existing automated tuning of RF power amplifiers is complicated, requiring both complicated test equipment and complicated algorithms.

### SUMMARY OF THE INVENTION

In accordance with a first aspect of the invention, a tunable impedance matching circuit is provided for tuning an active device, such as, e.g., a field effect transistor, in a RF power amplifier. The matching circuit includes an adjustable length transmission line for electrically coupling a RF signal between an active device and its source and a load. The length of the transmission line is adjusted to achieve selected performance characteristic(s) of the amplifier, such as, e.g., input return loss, output return loss or gain.

In accordance with another aspect of the invention, a method is provided for tuning an active device, e.g., a RF power transistor, used in an amplifier circuit. The method employs tuning an impedance matching circuit coupled to the active device, the matching circuit including a transmission line having an adjustable length. In an exemplary embodiment, the method includes measuring a performance characteristic of the device, such as, e.g., input return loss, and then adjusting the length of the transmission line to adjust the performance characteristic to a desired level.

In accordance with still another aspect of the invention, a method of manufacturing a power amplifier is provided. The method includes coupling an active device to a matching circuit comprising an adjustable length transmission line. A performance characteristic of the device is then measured, and the length of the transmission line is adjusted to achieve a desired change in the measured performance characteristic.

In embodiments of the forgoing, the transmission line initially has a length slightly greater than a quarter of a wavelength (“¼λ”) of a fundamental frequency of a RF signal being amplified, with the final (i.e., adjusted) length depending on whether the circuit is capacitively or inductively loaded. By way of example, the length of the transmission line may be adjusted using laser trimming.

Other aspects and features of the present invention will become apparent from the following description taken in conjunction with the accompanying drawings.

### BRIEF DESCRIPTION OF THE DRAWINGS

Preferred embodiments of the invention are illustrated by way of example, and not by way of limitation, in the figures of the accompanying drawings, in which like reference numerals refer to like components, and in which:

FIG. 1 is a schematic circuit diagram of an inductively coupled, tunable impedance matching circuit for a RF power amplifier circuit, according to one embodiment of the invention;

FIG. 2 is a schematic circuit diagram of a capacitively coupled, tunable impedance matching circuit for a RF power amplifier circuit, according to another embodiment of the invention;

FIG. 3 is a graph of the frequency response of a RF power amplifier circuit as a function of a length of a transmission line length of an impedance matching circuit, according to one aspect of the invention;

FIG. 4 is a schematic circuit diagram of a RF power amplifier circuit employing both input and output tunable impedance matching circuits, according to an embodiment of the invention; and

FIG. 5 is a Smith admittance chart illustrating how the frequency of a RF power amplifier circuit can be varied at substantially constant conductance, in accordance with one embodiment of the invention.

### DETAILED DESCRIPTION OF THE PREFERRED EMBODIMENTS

The present invention is directed to the tuning of RF power amplifiers for impedance matching. In particular, the invention involves tuning a performance characteristic of a power amplifier by employing an impedance matching circuit at the input, output, or both, of the active transistor element. In particular, embodiments of the tunable impedance matching circuit include both inductive and capacitively coupled matching structures incorporating a variable length transmission line.

More particularly, the transmission line preferably has an initial length slightly greater than ¼λ of a fundamental frequency of a RF signal being amplified. In order to tune the performance characteristic of the power amplifier, the length of the transmission line is adjusted, such that only the resonance of the impedance matching circuit, and not the resistance, is changed. The resulting length of the transmission line may be slightly greater, slightly less, or approximately the same as ¼λ of the findamental RF signal frequency, depending on whether the amplifier is capacitively loaded, inductively loaded, or has no reactance component, respectively. Thus, the invention may be applied in matching circuits employed in RF power amplifiers having reactive inputs.

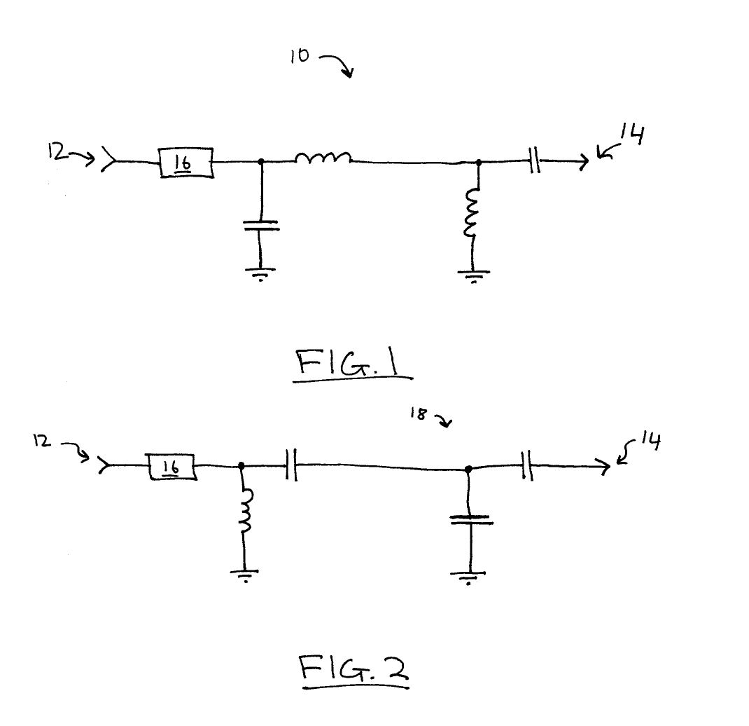

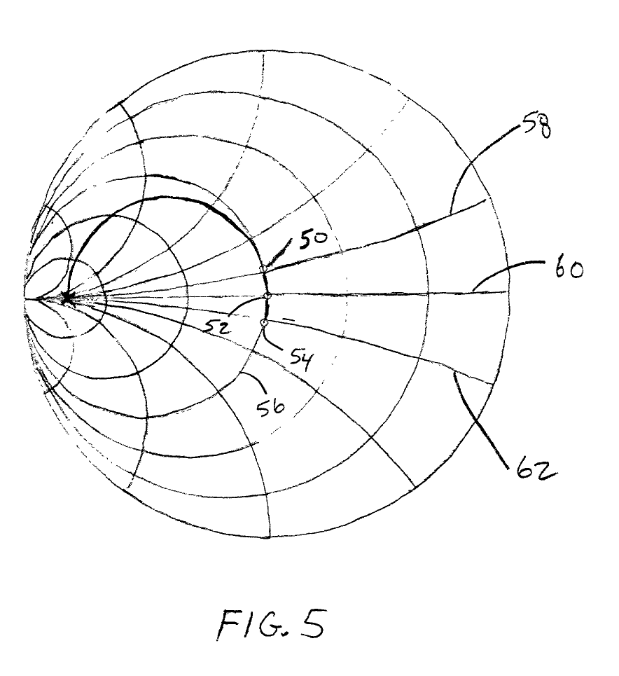

FIG. 1 is a schematic drawing of an inductively coupled, tunable impedance matching circuit (“tuning circuit”) 10 for use in a RF power amplifier circuit. The matching circuit 10 is adapted to be attached to a source 12 and a load 14, and may be employed as either an input matching element, or an output matching element, as is described in greater detail in conjunction with FIG. 4. In one embodiment, the matching circuit 10 comprises a circuit of passive components, which are selected depending on the particular application and device requirements.

In accordance with a general aspect of the invention, the tuning circuit 10 further comprises a variable length transmission line 16 for coupling the source 12 to the load 14. As part of the process for assembling a RF power amplifier circuit including the matching circuit 10, the length of the transmission line 16 is adjusted in order to tune a performance characteristic of the amplifier circuit. This may be accomplished, e.g., by laser trimming the physical length of the transmission line 16.

Notably, the resistance of the transformation of the transmission line 16 depends on its width, whereas the frequency of the transformation depends on its length. Therefore, by adjusting only the length of the transmission line 16, the resonance frequency of the matching circuit 10 can be changed, while the resistance at resonance is changed only slightly. More particularly, by definition, a ¼λ transmission line is 90 degrees at resonance. The impedance (ZO) of that transmission is determined by the desired transformation according to the geometric mean of the generator and load. As an example, to transform 5 ohms to 50 ohms, the width of a ¼λ transmission line is the geometric mean of the two impedances, or (5*50)^{0.5} ohms.

By way of example, the Smith admittance chart in FIG. 5 illustrates how the frequency 48 of a RF power amplifier circuit can be varied from 1.86 GHz (at point 50), to 1.96 GHz (at point 52), to 2.06 GHz (at point 54), at substantially constant 20 mmho conductance, or 50 ohms of resistance (line 56). Lines 58, 60 and 62 illustrate operating points of inductance (line 58), zero suseptance (line 60) and capacitance (line 62), respectively. Notably, it may be observed from the chart in FIG. 5 that as the frequency changes, the conductance remains constant for a significant range of frequencies.

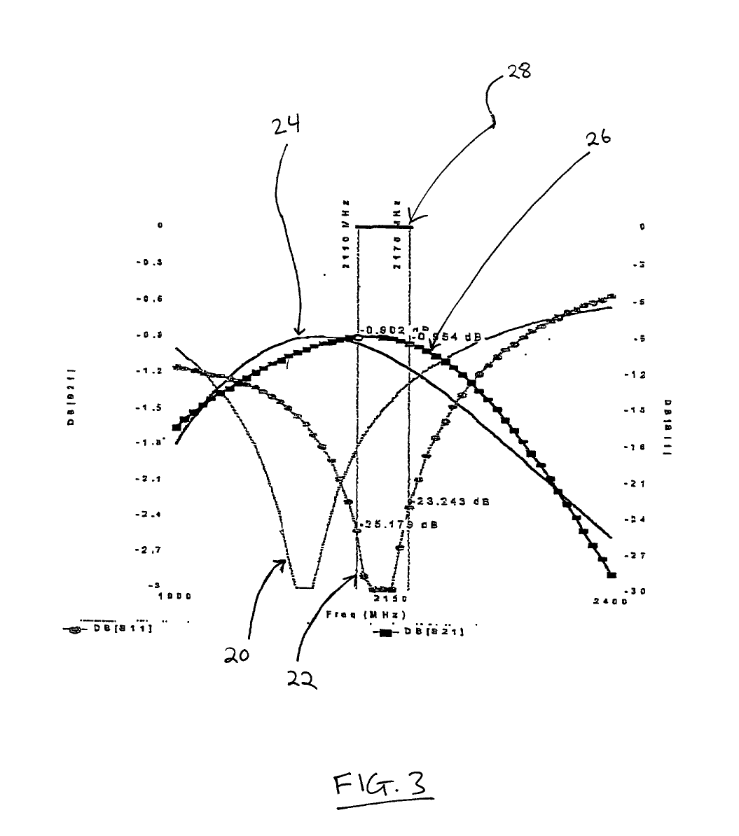

FIG. 2 is a schematic drawing of a capacitively coupled, tunable impedance matching circuit 18. As with the matching circuit 10 of FIG. 1, the matching circuit 18 also includes a variable length transmission line 16 for coupling a source 12 to a load 14. As with matching circuit 10, as part of the process for assembling a RF power amplifier circuit incorporating the matching circuit 18 as either an input or an output matching circuit, the tuning circuit 10 is tuned by adjusting the length of the transmission line 16.

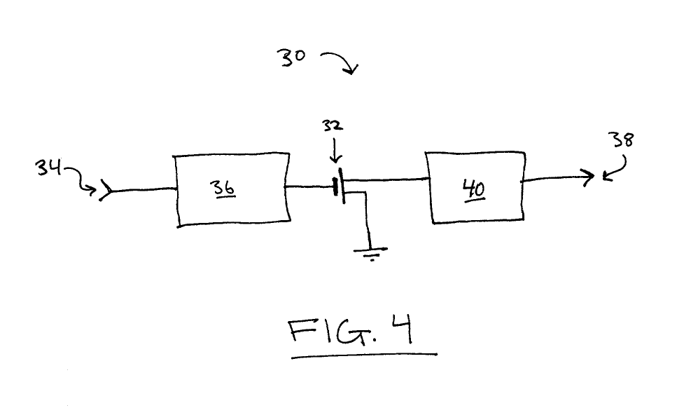

FIG. 3 shows the frequency response characteristics of an exemplary RF power amplifier circuit employing a matching circuit (tuning circuit) having a variable length transmission line 16 of circuits 10 and 18. Line 20 is a graph of the input return loss of the amplifier circuit, and line 24 is a graph of the gain/loss of the two-port circuit. During assembly of the amplifier circuit, e.g., when the amplifier circuit is initially laid out, one or more selected performance characteristics of the amplifier are measured using standard test equipment. For given application(s) of the amplifier, certain performance characteristics will be desired. Such measurable performance characteristics include input return loss, (e.g., as shown by line 20 in FIG. 3). Other measurable performance characteristics include, without limitation, gain and output return loss. As will be appreciated by those skilled in the art, numerous other performance characteristics may be selected without varying from the inventive concepts presented herein.

As noted above, due to the variability of the device characteristics, the desired performance characteristic(s) of the amplifier circuit are not necessarily achieved when the device is first laid out; hence, the need arises to tune the amplifier circuit to achieve the desired characteristics. For example, area 28 shows the frequency range where it might be desired to have the optimum input return loss of the amplifier circuit. In other words, it would be desirable to shift line 20 to the right until its minimum falls within area 28. By changing the length of the matching circuit transmission line according to known relationship, the input return loss can be predictably shifted, as shown in line 22.

FIG. 4 is a schematic drawing illustrating the use of adjustable matching circuits 36 and 40, e.g., such as either of circuits 10 and 18 in FIGS. 1 and 2, in an exemplary RF power amplifier circuit 30. The amplifier circuit 30 includes an active RF device 32, e.g., a field effect transistor. The transistor 32 receives an input signal at its gate terminal from a source 34, which is coupled to the gate terminal via input matching circuit 36. An amplified output signal is transmitted from a drain terminal of the transistor 32 to a load 38, which is coupled to the drain via output matching circuit 40. The matching circuits 36 and 40 each include a variable length transmission line, as in matching circuits 10 and 18 of FIGS. 1 and 2.

In accordance with this aspect of the invention, the values of the components in each of the matching circuits 36 and 40 are initially determined according to the respective source and load impedance required by the transistor device 32. After assembling the amplifier circuit 30, at least in part, each matching circuit 36 and 40 is tuned to achieve desired electrical performance by changing the length of the respective transmission lines therein.

While preferred embodiments and applications have been shown and described, as can be appreciated by those of ordinary skill in the art, the invention can be embodied in other specific forms without departing from the inventive concepts contained herein. The presently disclosed embodiments, therefore, should be considered as illustrative, and not restrictive.

What is claimed is:

1. An impedance matching circuit for tuning an active device, comprising:
a transmission line for electrically coupling a radio frequency signal between a source and a load, one of the source and load comprising the active device, wherein the length of the transmission line is adjusted to achieve a selected performance characteristic of the device.

2. The matching circuit of claim 1, wherein the performance characteristic is input return loss.

3. The matching circuit of claim 1, wherein the performance characteristic is output return loss.

4. The matching circuit of claim 1, wherein the performance characteristic is gain.

5. The matching circuit of claim 1, wherein the length of the transmission line is adjusted by laser trimming the transmission line.

6. The matching circuit of claim 1, wherein the active device is a field effect transistor.

7. A method of tuning an active radio frequency (RF) device, the method employing tuning an impedance matching circuit coupled to the device, the matching circuit including an adjustable length transmission line, the method comprising:
measuring a performance characteristic of the device; and
adjusting the length of the transmission line to adjust the performance characteristic.

8. The method of claim 7, wherein the performance characteristic is input return loss.

9. The method of claim 7, wherein the performance characteristic is output return loss.

10. The method of claim 7, wherein the performance characteristic is gain.

11. The method of claim 7, wherein the length of the transmission line is adjusted by laser trimming the transmission line.

12. The method of claim 7, wherein the active device is a field effect transistor.

13. A method of manufacturing a power amplifier, comprising:
coupling an active device to a matching circuit, the matching circuit comprising a transmission line having an adjustable length;
measuring a performance characteristic of the device; and
adjusting the length of the transmission line to achieve a change in the measured performance characteristic.

14. The method of claim 13, wherein the device is a field effect transistor.

15. The method of claim 13, wherein the length of the transmission line is adjusted by laser trimming the transmission line.

16. The method of claim 13, wherein the performance characteristic is input return loss.

17. The method of claim 13, wherein the performance characteristic is output return loss.

18. The method of claim 13, wherein the performance characteristic is gain.
